(19) United States
(12) Patent Application Publication
(10) Pub. No.: US 2023/0309249 A1
(43) Pub. Date: Sep. 28, 2023

(54) ELECTRONIC APPARATUS

(71) Applicant: LENOVO (SINGAPORE) PTE. LTD., SINGAPORE (SG)

(72) Inventors: Hiroaki Kinoshita; Yalu Liu, YOKOHAMA (JP); Daisuke Takahashi, YOKOHAMA (JP); Tetsuya Sano, YOKOHAMA (JP)

(73) Assignee: LENOVO (SINGAPORE) PTE. LTD., SINGAPORE (SG)

(21) Appl. No.: 18/160,784

(22) Filed: Jan. 27, 2023

(30) Foreign Application Priority Data
Mar. 24, 2022 (JP) 202248333

(51) Int. Cl. G06F 1/16; H05K 5/02

(52) U.S. Cl. CPC H05K 5/0226; G06F 1/1616

(57) ABSTRACT

An electronic apparatus has a first chassis member, a second chassis member adjacent to the first chassis member, and a hinge device that relatively rotatably connects the first chassis member and the second chassis member between a 0-degree posture and a 180-degree posture The adjacent end portion of the first chassis member is provided with a stopper projection that comes into contact with the adjacent end portion of the second chassis member in the 180-degree posture. The stopper projection is provided near a center of a thickness W of the first chassis member in the adjacent end portion the first chassis member.

### BACKGROUND OF THE INVENTION

### Field of the Invention

The present invention relates to an electronic apparatus in which a first chassis member and a second chassis member are connected by a hinge device.

### Description of the Related Art

In recent years, electronic apparatuses such as PCs and smartphones that have a touch panel type liquid crystal display and do not have a physical keyboard are rapidly spreading. The display of this type of electronic apparatus is desired to be large when in use, but it is desired to be made smaller when not in use. Therefore, Japanese Patent No. 6453413 proposes an electronic apparatus configured such that not only a chassis member but also a display is capable of being folded by using a flexible display such as organic electro luminescence (EL).

In the electronic apparatus described in Japanese Patent No. 6453413, a first chassis member and a second chassis member are connected by a hinge device, and are relatively rotatable between a 0-degree posture in which the first chassis member and the second chassis member are folded so as to overlap each other in a surface normal direction and a 180-degree posture in which they are aligned in a direction perpendicular in the surface normal direction. This electronic apparatus can be used in the same way as a tablet PC with a large area when it is placed in the 180-degree posture. The hinge device is provided with a torque mechanism that applies torque so that the first chassis member and the second chassis member can be held at any angle.

### SUMMARY OF THE INVENTION

In such an electronic apparatus, it is desirable that the angle formed by the first chassis member and the second chassis member is exactly 180 degrees in the 180-degree posture. This is because when the angle is 180 degrees or more or 180 degrees or less, a gap is generated when it is placed on a desk and a user feels uncomfortable. Therefore, it is conceivable to provide some kind of stopper so that the first chassis member and the second chassis member are at 180 degrees. Since the hinge device itself is set to be able to move 180 degrees or more in consideration of some motion margin, the stopper may be provided on either the first chassis member or the second chassis member, and may be configured to come into contact with the other motion-limiting surface in the 180-degree posture.

By the way, as described above, the hinge device is provided with the torque mechanism. Therefore, even the stopper comes into contact with the motion-limiting surface in the 180-degree posture, there is a concern that a rotation angle returns to the opposite side because of an influence of a residual torque of the torque mechanism, and the rotation angle is slightly less than 180 degrees.

The present invention has been made in view of the above problems, and an object of the present invention is to provide an electronic apparatus in which an angle between the first chassis member and the second chassis member can be more accurately set to 180 degrees.

In order to solve the above-described problems and achieve the object, an electronic apparatus according to an aspect of the present invention includes: a first chassis member; a second chassis member adjacent to the first chassis member; and a hinge device that relatively rotatably connects the first chassis member and the second chassis member between a first posture in which the first chassis member and the second chassis member are folded so as to overlap each other in a surface normal direction and a second posture in which the first chassis member and the second chassis member are aligned in a direction perpendicular to the surface normal direction, in which in the second posture, a first side wall of the first chassis member faces a second side wall of the second chassis member, the first side wall is provided with a stopper projection that comes into contact with the second side wall in the second posture, and the stopper projection is provided near a center of a thickness of the first chassis member in the surface normal direction in the first side wall. As a result, the angle between the first chassis member and the second chassis member can be more accurately set to 180 degrees.

The hinge device may have a main body block, a first rotation shaft member pivotally supporting the first chassis member with respect to the main body block, a second rotation shaft member pivotally supporting the second chassis member with respect to the main body block, and a synchronization mechanism synchronizing rotation of the first chassis member and the second chassis member with respect to the main body block. At least a part of the stopper projection may be included within a range of a width of the first rotation shaft member and the second rotation shaft member in the surface normal direction. Since the first rotation shaft member and the second rotation shaft member are pivotally supported by the main body block, a distance between the first rotation shaft member and the second rotation shaft member does not decrease. Therefore, in a case in which at least a part of the stopper projection is included within the range of the width, it becomes easier to temporarily open the angle between the first chassis member and the second chassis member to 180 degrees or more.

A display may be provided over the first chassis member and the second chassis member and may have a folding region that is folded according to relative rotation of the first chassis member and the second chassis member. In this aspect, since the first chassis member and the second chassis member are more accurately at 180 degrees, the folding region becomes flat and the visibility of the display is improved.

The above-described aspects of present invention enable the first chassis member and the second chassis member to be temporarily opened by 180 degrees or more by providing the stopper projection near the center of the thickness of the first side wall in the surface normal direction, and then it is slightly reversed by the action of the residual stress of the hinge device, so that the 180-degree posture can be set more accurately.

### BRIEF DESCRIPTION OF THE DRAWINGS

FIG. 1 is a perspective view schematically illustrating a state in which an electronic apparatus according to an embodiment is closed and in a 0-degree posture.

FIG. 2 is a perspective view schematically illustrating a state in which the electronic apparatus illustrated in FIG. 1 is opened and in a 180-degree posture.

FIG. 3 is a schematic cross-sectional view of an electronic apparatus.

FIG. 4 is a schematic cross-sectional view illustrating a state in which the electronic apparatus illustrated in FIG. 3 is in the 0-degree posture.

FIG. 5 is an enlarged perspective view of an end portion of the electronic apparatus in the 0-degree posture.

FIG. 6 is an enlarged perspective view of an end portion of the electronic apparatus in the 180-degree posture.

FIGS. 7A and 7B are views illustrating an electronic apparatus, FIG. 7A is a schematic side view illustrating a state of the 180-degree posture, and FIG. 7B is a schematic side view illustrating a state of being slightly opened from 180 degrees.

FIGS. 8A and 8B are views illustrating an electronic apparatus according to a comparative example, FIG. 8A is a schematic side view illustrating a state of the 180-degree posture, and FIG. 8B is a schematic side view illustrating a state of being slightly closed from 180 degrees.

FIG. 9 is a schematic diagram illustrating a frame member and an aspect of a process of attaching a display to the frame member in manufacturing an electronic apparatus.

### DETAILED DESCRIPTION OF THE INVENTION

Hereinafter, an electronic apparatus according to the present invention will be described in detail with preferred embodiments with reference to the accompanying drawings.

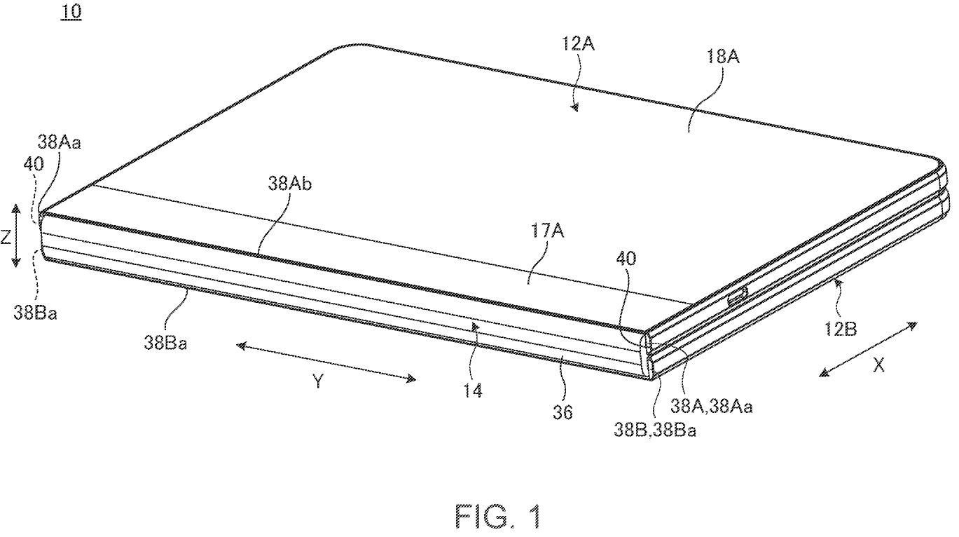

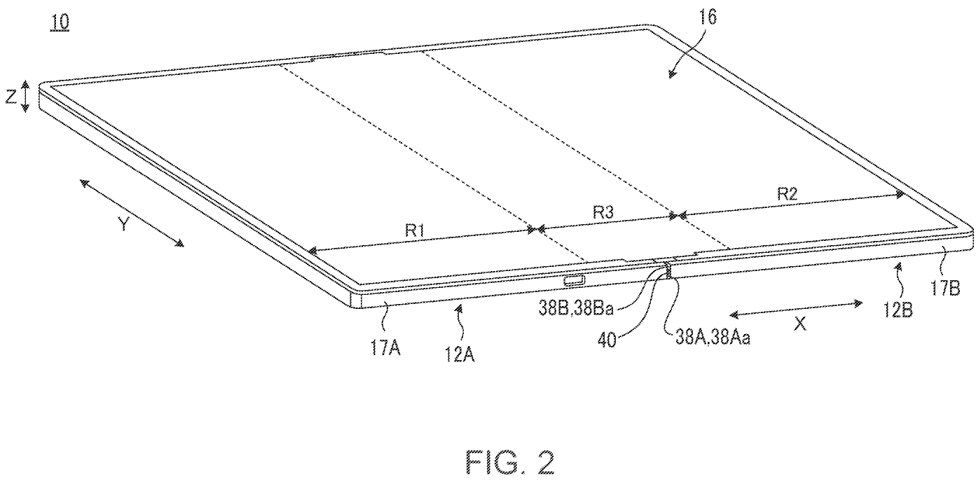

FIG. 1 is a perspective view schematically illustrating a state in which an electronic apparatus 10 according to an embodiment is closed and in a 0-degree posture. FIG. 2 is a perspective view schematically illustrating a state in which the electronic apparatus 10 illustrated in FIG. 1 is opened and in a 180-degree posture.

As illustrated in FIGS. 1 and 2, the electronic apparatus 10 includes a first chassis member 12A and a second chassis member 12B, a hinge device 14, and a display 16. The electronic apparatus 10 of the present embodiment exemplifies a tablet PC or a laptop PC that is capable of being folded like a book. The electronic apparatus 10 may be a smartphone, a portable game machine, or the like.

Each chassis member 12A and 12B is disposed adjacent to each other. Each chassis member 12A and 12B appropriately mounts various electronic components such as a motherboard mounting a CPU, a battery device, an antenna module, and a communication module.

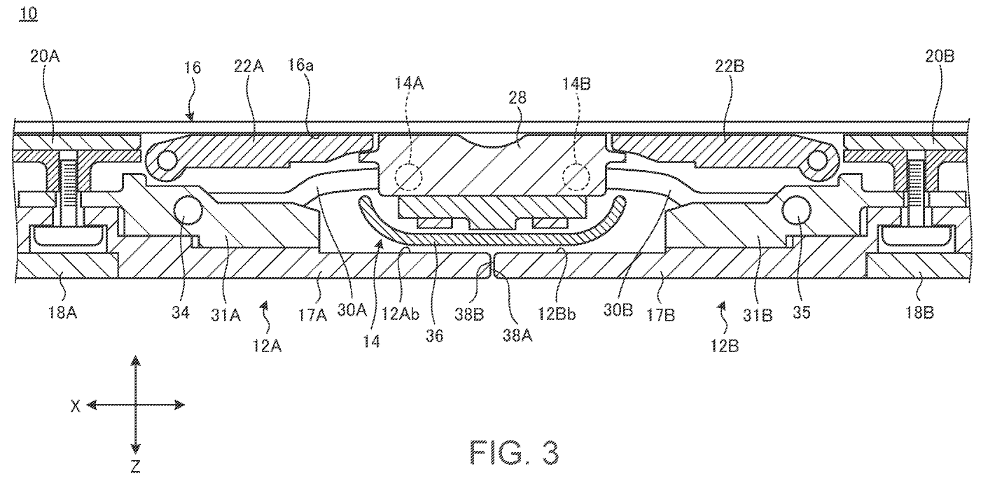

The first chassis member 12A includes a frame member 17A and a cover member 18A. The frame member 17A is a rectangular frame-shaped member having standing walls formed on three sides other than an adjacent end portion 38A adjacent to the second chassis member 12B. The cover member 18A is a plate-shaped member that closes a rear surface opening of the frame member 17A (see also FIG. 3). Similarly, the second chassis member 12B includes a frame member 17B having standing walls on three sides other than an adjacent end portion 38B adjacent to the first chassis member 12A, and a cover member 18B that closes a rear surface opening of the frame member 17B. Front surface openings of the frame members 17A and 17B are closed with the display 16.

Each member 17A, 17B, 18A, and 18B is made of, for example, a metal member such as stainless steel, magnesium, or aluminum, or a fiber-reinforced resin plate containing reinforcing fibers such as carbon fiber, and the like.

The hinge device 14 connects the chassis members 12A and 12B so as to be relatively rotatable between the 0-degree posture and the 180-degree posture. Strictly speaking, however, the hinge device 14 is set so as to be able to move at 180 degrees or more (for example, about 185 degrees) in consideration of some motion margin. The hinge device 14 also functions as a rear cover that hides the gap between the adjacent end portions 38A and 38B formed in the 0-degree posture illustrated in FIG. 1. The display 16 extends over the chassis members 12A and 12B.

Hereinafter, as for the electronic apparatus 10, description is performed while a direction in which the chassis members 12A and 12B are aligned is called an X direction, a direction along the adjacent end portions 38A and 38B orthogonal to the X direction is called a Y direction, and a thickness direction of the chassis members 12A and 12B is called a Z direction. As for the angular posture between the chassis members 12A and 12B, description is performed while a state in which the chassis members 12A and 12B are folded so as to overlap each other in the surface normal direction (that is, Z direction) is called the 0-degree posture (first posture, see FIG. 1), and a state in which the chassis members 12A and 12B are aligned in a direction perpendicular to the surface normal direction (X direction) is called the 180-degree posture (second posture, see FIG. 2). It is possible to call the posture between 0 and 180 degrees by appropriately carving the angle, and, for example, a state in which the surface normal directions of the chassis members 12A and 12B are orthogonal to each other is a 90-degree posture. These angles are for convenience of description, and an actual product may of course have angular positions slightly deviated from the exact angular positions indicated by angle numbers.

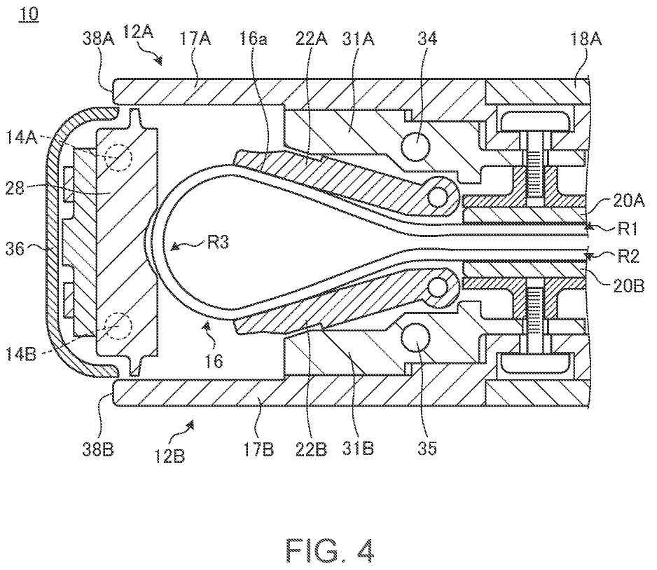

FIG. 3 is a schematic cross-sectional view of the electronic apparatus 10. FIG. 4 is a schematic cross-sectional view illustrating a state in which the electronic apparatus 10 illustrated in FIG. 3 is in the 0-degree posture.

In the 0-degree posture illustrated in FIGS. 1 and 4, the chassis members 12A and 12B are in a state of being folded in half. The display 16 is a paper-shaped flexible display formed of organic EL. At the 0-degree posture, the display 16 is disposed such that a first region R1 on the side of the first chassis member 12A faces a second region R2 on the side of the second chassis member 12B, which are illustrated in FIG. 2, and a folding region R3, which is a boundary region between the regions R1 and R2, is in a state of being folded in an arc shape. In the 180-degree posture illustrated in FIG. 2, the chassis members 12A and 12B are disposed side by side with each other. At this time, the display 16 has the regions R1 and R2 and the folding region R3 disposed side by side on a XY plane, and forms a flat plate shape as a whole.

The display 16 has the first region R1 relatively fixed to the first chassis member 12A and the second region R2 relatively fixed to the second chassis member 12B. Specifically, a rear surface 16a of the first region R1 is fixed to the first chassis member 12A via a first plate 20A (see FIG. 3), and a rear surface 16a of the second region R2 is fixed to the second chassis member 12B via a second plate 20B (see FIG. 3). The first plate 20A is adjacent to a first support plate 22A of the hinge device 14, and the second plate 20B is adjacent to a second support plate 22B of the hinge device 14 (see FIG. 3).

The folding region R3 of the display 16 is capable of relatively moving with respect to the chassis members 12A and 12B. In the 180-degree posture, the rear surface 16a of the folding region R3 is supported by the hinge main body 28 and the support plates 22A and 22B. In the 0-degree posture, the folding region R3 is folded in an arc shape, a part of the rear surface 16a is supported by the support plates 22A and 22B, and most portions of the rear surface 16a are separated from the hinge device 14.

As illustrated in FIG. 3, the hinge device 14 has a hinge main body (main body block) 28, the first support plate 22A, the second support plate 22B, a first link arm 30A, and a second link arm 30B.

The hinge main body 28 is provided at a position straddling the adjacent end portions 38A and 38B of the chassis members 12A and 12B, and extends over the substantially entire length in the Y direction along the adjacent end portions 38A and 38B. The hinge main body 28 is a block-shaped component formed of a metal material such as aluminum. The hinge main body 28 supports a first hinge shaft (first rotation shaft member) 14A and a second hinge shaft (second rotation shaft member) 14B aligned in the X direction in the 180-degree posture.

A first end portion of the first link arm 30A is rotatably supported on the first hinge shaft 14A. A first end portion of the second link arm 30B is rotatably supported on the second hinge shaft 14B.

A second end portion of the first link arm 30A is connected to a first bracket 31A using a rotation shaft 34 so as to be relatively rotatable. The first bracket 31A is fixed to an inner surface 12Ab of the first chassis member 12A using screws or the like. A second end portion of the second link arm 30B is connected to a second bracket 31B using a rotation shaft 35 so as to be relatively rotatable. The second bracket 31B is fixed to an inner surface 12Bb of the second chassis member 12B using screws or the like.

A plurality of link arms 30A and 30B and brackets 31A and 31B are aligned along the Y direction, which is a longitudinal direction of the hinge main body 28. As a result, the hinge main body 28 connects the chassis members 12A and 12B so as to be relatively rotatable. In the hinge main body 28, a gear mechanism (synchronization mechanism) for synchronizing the rotational movement between the chassis members 12A and 12B and a torque mechanism for applying a predetermined rotational torque to the rotational movement between the chassis members 12A and 12B, and the like are also provided. As illustrated in FIG. 1, a rear cover component 36 serving as a decorative cover is attached to a rear surface of the hinge main body 28.

The support plates 22A and 22B are plates that are formed of a metal material such as aluminum, extend in the Y direction, and have bilaterally symmetrical shapes. The support plates 22A and 22B are pivotally supported with respect to brackets, on which the link arms 30A and 30B are pivotally supported, thereby being swingable. The support plates 22A and 22B are disposed on the left and right sides of the hinge main body 28 in the 180-degree posture, and their front surfaces are disposed on the same plane as the front surface of the hinge main body 28. As a result, the hinge device 14 is capable of supporting the folding region R3 (see FIG. 2) of the display 16 in the 180-degree posture.

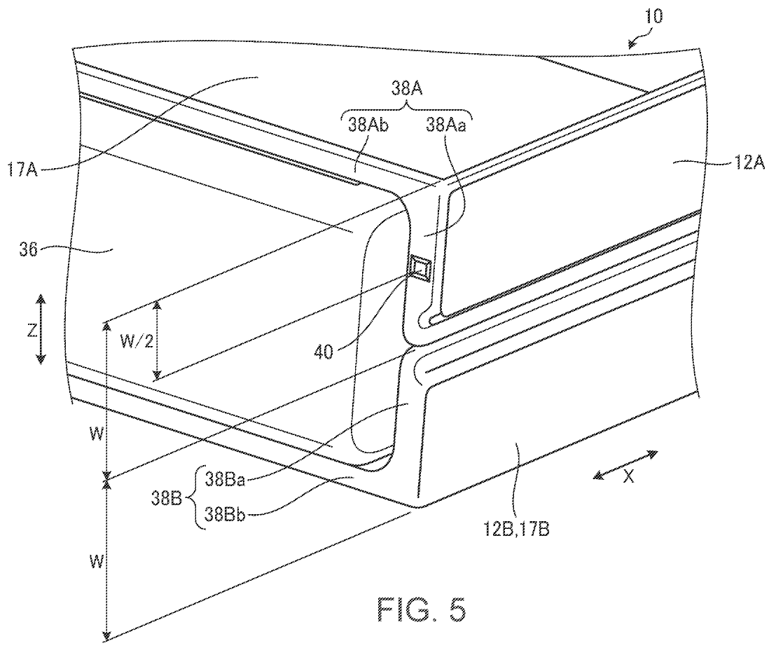

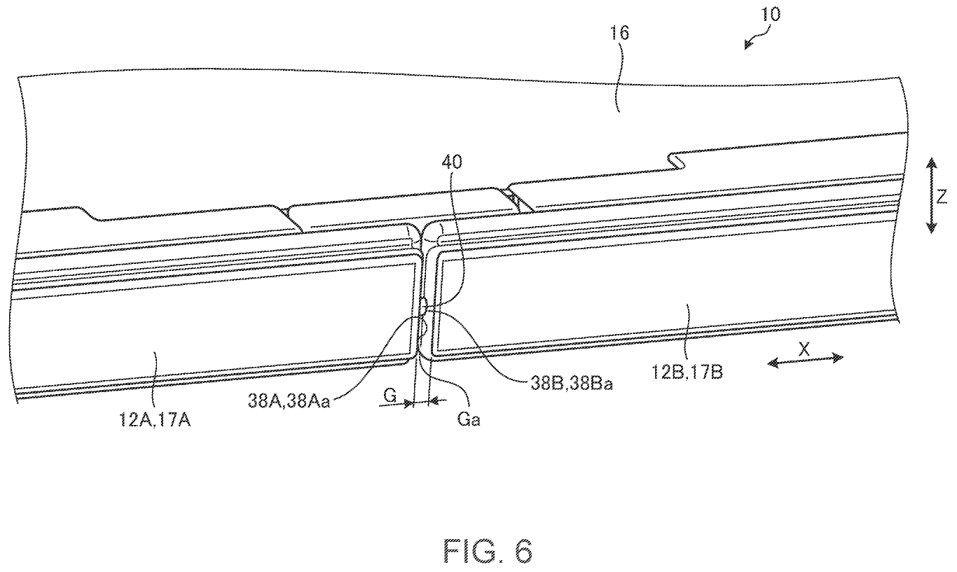

FIG. 5 is an enlarged perspective view of an end portion of the electronic apparatus 10 in the 0-degree posture. FIG. 6 is an enlarged perspective view of an end portion of the electronic apparatus 10 in the 180-degree posture.

The first chassis member 12A and the second chassis member 12B have a thickness W in the Z direction. The adjacent end portion 38A of the first chassis member 12A is formed so as to surround three sides of the rear cover component 36, and is configured by a pair of longitudinal end portions (first side wall) 38Aa (see also FIG. 1) along the Z direction at both left and right ends and a lateral end portion 38Ab along the Y direction. Similarly, the adjacent end portion 38B of the second chassis member 12B is formed so as to surround three sides of the rear cover component 36, and is configured by a pair of longitudinal end portions (second side wall) 38Ba along the Z direction at both left and right ends and a lateral end portion 38Bb along the Y direction. The longitudinal end portions 38Aa and 38Ba are formed over the entire length in the Z direction. The lateral end portions 38Ab and 38Bb are formed over the entire length in the Y direction.

Although the adjacent end portions 38A and 38B have a narrow area in the present embodiment, the adjacent end portions can be regarded as constituting a part of the side walls of the first chassis member 12A and the second chassis member 12B. Although the longitudinal end portions 38Aa and 38Ba and the lateral end portions 38Ab and 38Bb are narrow, depending on the design conditions, the rear cover component 36 may be made smaller and the area occupied by the adjacent end portions 38A and 38B may be widened by that amount. The adjacent end portion 38A and the adjacent end portion 38B face each other with a narrow gap G therebetween in the 180-degree posture (see FIG. 6).

The longitudinal end portion 38Aa is provided with a stopper projection 40 that comes into contact with the longitudinal end portion 38Ba in the 180-degree posture. The stopper projections 40 are provided on the pair of longitudinal end portions 38Aa (see FIG. 1). The stopper projection 40 is small and has a projection height equal to the gap G.

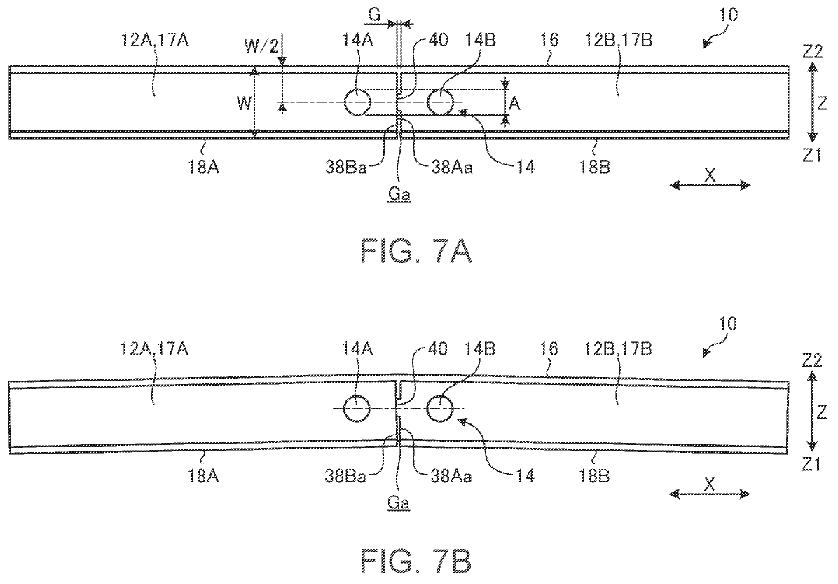

FIGS. 7A and 7B are views illustrating the electronic apparatus 10, FIG. 7A is a schematic side view illustrating a state of the 180-degree posture, and FIG. 7B is a schematic side view illustrating a state of being slightly opened more than 180 degrees. The stopper projection 40 is provided at the center of the thickness W of the first chassis member 12A in the longitudinal end portion 38Aa, that is, at a position of the thickness W/2. More specifically, the stopper projection 40 is included within a range of a width A of the first hinge shaft 14A and the second hinge shaft 14B in the Z direction. Since the stopper projection 40 comes into contact with the facing longitudinal end portion 38Ba in the 180-degree posture, the longitudinal end portion 38Ba serves as the motion-limiting surface.

In the electronic apparatus 10, the stopper projection 40 is provided at the center in the thickness direction, so that a rear side gap Ga is formed on the rear side (arrow Z1 side in FIGS. 7A and 7B) closer to the cover members 18A and 18B than the stopper projection 40.

As illustrated in FIG. 7B, in the electronic apparatus 10, the hinge device 14 has a motion margin of 180 degrees or more, and furthermore, there is the rear side gap Ga on the rear side of the stopper projection 40. Therefore, the rear side gap Ga becomes deformable, and the angle between the first chassis member 12A and the second chassis member 12B is temporarily opened slightly from 180 degrees (for example, about 182 degrees or 183 degrees) with the stopper projection 40 as a fulcrum.

Then, since some residual torque is generated in the torque mechanism of the hinge device 14, in a case in which it is manually opened to the state illustrated in FIG. 7B and then opened, it can be slightly reversed to the 180-degree posture illustrated in FIG. 7A. In particular, by placing the electronic apparatus 10 on a flat surface such as a desk, it is possible to take the 180-degree posture fairly accurately following the flat surface.

Since the first chassis member 12A and the second chassis member 12B are relatively rotated by the pivotal support of the first hinge shaft 14A and the second hinge shaft 14B through the hinge main body 28 and the stopper projection 40 is disposed within the range of the width A of these first hinge shaft 14A and second hinge shaft 14B in the Z direction, it can be appropriately and temporarily opened by 180 degrees or more. However, the stopper projection 40 does not have to be entirely within the range of the width A, the effect is almost the same as long as at least a part thereof is within the range of the width A near the center of the thickness W of the adjacent end portion 38A.

In this manner, in the electronic apparatus 10, the stopper projection 40 is provided near the center of the thickness W of the adjacent end portion 38A, so that the first chassis member 12A and the second chassis member 12B are temporarily opened by 180 degrees or more, and then slightly reversed by the action of the residual stress of the hinge device 14, so that the 180-degree posture can be set more accurately. Therefore, when the electronic apparatus 10 is placed on the desk, both ends in the X direction do not float, and the user does not feel uncomfortable. In addition, in the electronic apparatus 10 returned to the 180-degree posture in this way, the stopper projection 40 still comes into contact with the adjacent end portion 38B, functions as a stopper, and is stable. Further, since the electronic apparatus 10 is in the correct 180-degree posture, the display 16 is planar, and the folding region R3 (see FIG. 2) is not folded, thereby improving visibility.

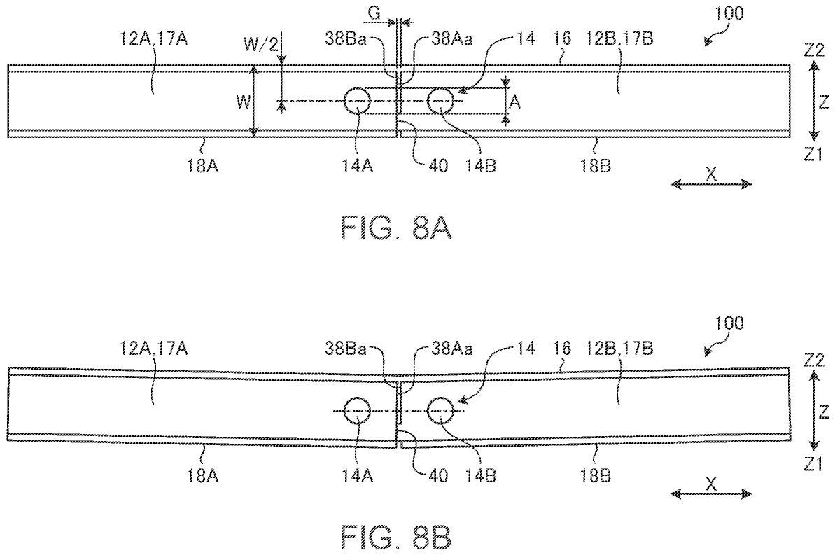

FIGS. 8A and 8B are views illustrating an electronic apparatus 100 according to a comparative example, FIG. 8A is a schematic side view illustrating a state of the 180-degree posture, and FIG. 8B is a schematic side view illustrating a state of being slightly closed from 180 degrees. In the electronic apparatus 100, the stopper projection 40 is provided at a Z1 side end of the adjacent end portion 38A of the first chassis member 12A.

In the electronic apparatus 100 according to the comparative example, in a case in which the angle between the first chassis member 12A and the second chassis member 12B is opened from the 0-degree posture or any other angle, the stopper projection 40 eventually comes into contact with the adjacent end portion 38B and it can be temporarily opened up to the 180-degree posture illustrated in FIG. 8A. However, since the electronic apparatus 100 does not have the rear side gap Ga in the above-described electronic apparatus 10, there is no motion margin, and the electronic apparatus 100 cannot be opened to 180 degrees or more.

More specifically, since the first hinge shaft 14A and the second hinge shaft 14B are pivotally supported by the hinge main body 28 (see FIG. 3), the distance between them does not decrease. The distance between the adjacent end portion 38A and the adjacent end portion 38B can be reduced in a portion closer to the Z1 side than the width A range, that is, the portion of the rear side gap Ga in the electronic apparatus 10. Since the electronic apparatus 100 according to the comparative example is provided with the stopper projection 40 at this portion, the electronic apparatus 100 cannot be opened by 180 degrees or more. As a result, the residual stress of the hinge device 14 causes the hinge device 14 to slightly return to the opposite side, and both ends in the X direction are in a floating state, which may give a sense of discomfort to the user. As described above, the electronic apparatus 10 according to the present embodiment does not have such a problem.

Although not illustrated, assuming that the stopper projection 40 is provided at the Z2 side end of the adjacent end portion 38A of the first chassis member 12A, a sufficient function as a stopper cannot be obtained and it may become unstable. Therefore, it is desirable to provide the stopper projection 40 near the center of the thickness W as described above.

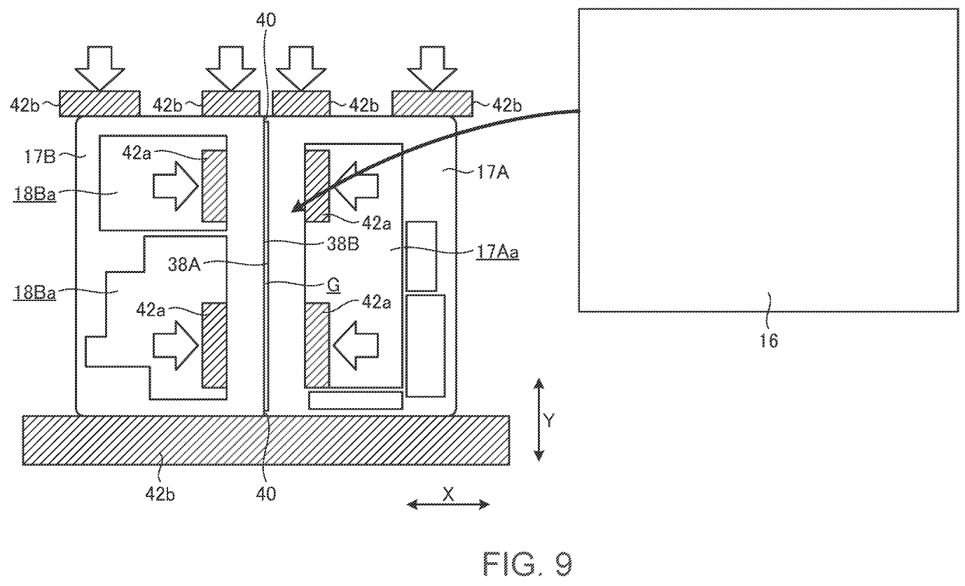

FIG. 9 is a schematic diagram illustrating an aspect of a process of attaching the display 16 to the frame member 17A and the frame member 17B in manufacturing the electronic apparatus 10. In this process, the frame member 17A and the frame member 17B are pressed by a plurality of jigs 42a and a plurality of jigs 42b.

The jig 42b presses the frame member 17A and the frame member 17B so as to compress them in the Y direction. Among the jigs 42b, the lower one in FIG. 9 is elongated so as to be common to the frame member 17A and the frame member 17B. Among the jigs 42b, the upper one in FIG. 9 is a separate body for the frame member 17A and the frame member 17B, and two of each are provided and can be pressed in a well-balanced manner.

The jig 42a presses the frame member 17A and the frame member 17B so as to compress them in the X direction. Four of the jigs 42a are provided so as to face each other in pairs, and the jigs 42a can be pressed in a well-balanced manner. The jigs 42a are provided in hollow portions 17Aa and 18Ba of the frame members 17A and 17B, and can effectively press against the adjacent end portions 38A and 38B.

In this process, the frame member 17A and the frame member 17B are compressed by a minute amount in each of the X direction and the Y direction due to the pressing action of the jigs 42a and 42b. In addition, in the X direction, the frame member 17A and the frame member 17B are in contact with each other via a pair of stopper projections 40. Since the stopper projection 40 is provided near the middle of the thickness W as described above (see FIGS. 7A and 7B), the stopper projection 40 can be pressed in a well-balanced manner by the jig 42a. The pressing force by the jigs 42a and 42b is a minimum necessary load for preventing a gap between the stopper projection 40 and the contacted portion. In a case in which the display 16 is not completely opened at 180 degrees, the display 16 is left in the center and wrinkles are generated. However, in a case in which the display 16 is completely opened at 180 degrees, the wrinkles of the display 16 can be prevented.

The present invention is not limited to the above-described embodiment, and it is needless to say that the present invention can be freely changed without departing from the gist of the present invention.

1. An electronic apparatus comprising:
a first chassis member;
a second chassis member adjacent to the first chassis member; and
a hinge device that rotatably connects the first chassis member and the second chassis member between a first posture in which the first chassis member and the second chassis member are folded so as to overlap each other in a surface normal direction and a second posture in which the first chassis member and the second chassis member are aligned in a direction perpendicular to the surface normal direction, wherein
in the second posture, a first side wall of the first chassis member faces a second side wall of the second chassis member,
the first side wall has a stopper projection that comes into contact with the second side wall in the second posture, and
the stopper projection is near a center of a thickness of the first chassis member in the surface normal direction in the first side wall.

2. The electronic apparatus according to claim 1, wherein
the hinge device has:
a main body block,
a first rotation shaft member pivotally supporting the first chassis member with respect to the main body block,
a second rotation shaft member pivotally supporting the second chassis member with respect to the main body block, and
at least a part of the stopper projection is within a range of a width of the first rotation shaft member and the second rotation shaft member in the surface normal direction.

3. The electronic apparatus according to claim 1, further comprising:
a display over the first chassis member and the second chassis member and has a folding region that is folded according to relative rotation of the first chassis member and the second chassis member.
